(19) United States
(12) Patent Application Publication
(10) Pub. No.: US 2020/0087788 A1
(43) Pub. Date: Mar. 19, 2020

(54) MULTIPLE CHANNEL SHOWERHEADS

(71) Applicant: APPLIED MATERIALS, INC., Santa Clara, CA (US)

(72) Inventors: Tien Fak Tan, Campbell, CA (US); Saravjeet Singh, Sunnyvale, CA (US); Tae Won Kim, San Jose, CA (US)

(73) Assignee: APPLIED MATERIALS, INC., Santa Clara, CA (US)

(21) Appl. No.: 16/132,796

(22) Filed: Sep. 17, 2018

(51) Int. Cl. C23C 16/455; C23C 16/509

(52) U.S. Cl. CPC C23C 16/45565; H01L 21/67017; C23C 16/509

(57) ABSTRACT

Exemplary semiconductor showerheads may include a first plate characterized by a first surface in which a plurality of first apertures are defined, and further characterized by a second surface opposite the first surface and from which extends a plurality of annular members. Each annular member of the plurality of annular members may extend from a separate first aperture of the plurality of first apertures. A channel may be defined by each first aperture and corresponding annular member. The showerheads may also include a second plate coupled with the first plate and characterized by a first surface facing the first plate and a second surface opposite the first surface. A plurality of second apertures may be defined through the second plate within an internal area of the second plate. Each annular member of the plurality of annular members may extend within a separate second aperture of the plurality of second apertures.

### TECHNICAL FIELD

The present technology relates to semiconductor processes and equipment. More specifically, the present technology relates to processing system chamber showerheads.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Dry etches produced in local plasmas formed within the substrate processing region can penetrate more constrained trenches and exhibit less deformation of delicate remaining structures. However, as integrated circuit technology continues to scale down in size, the equipment that delivers the precursors can impact the uniformity and quality of the precursors and plasma species used.

Thus, there is a need for improved system components that can be used in plasma environments effectively while providing suitable degradation profiles. These and other needs are addressed by the present technology.

### SUMMARY

Exemplary semiconductor showerheads may include a first plate characterized by a first surface in which a plurality of first apertures are defined. The first plate may be further characterized by a second surface opposite the first surface and from which second surface extend a plurality of annular members. Each annular member of the plurality of annular members may extend from a separate first aperture of the plurality of first apertures. A channel may be defined by each first aperture and corresponding annular member. The showerheads may also include a second plate coupled with the first plate. The second plate may be characterized by a first surface facing the first plate and a second surface opposite the first surface. A plurality of second apertures may be defined through the second plate within an internal area of the second plate. Each annular member of the plurality of annular members may extend within a separate second aperture of the plurality of second apertures

In some embodiments, each annular member of the plurality of annular members may extend a distance through a corresponding second aperture beyond the second surface of the second plate. The second plate may define a recessed ledge at an internal radius of the second plate, and the recessed ledge may define a boundary between the internal area and an external area of the second plate. The first surface of the second plate may be coated with a first material along the internal area of the first surface of the second plate. The first surface of the second plate may be coated with a second material along at least a portion of the external area of the first surface of the second plate, and the second material may be different from the first material. The second plate may define a first trench extending about the internal area radially outward of the recessed ledge, and a first sidewall may be defined between the first trench and the internal area of the second plate. A plurality of first notches may be defined in the first sidewall at the first surface of the second plate and radially distributed about the first sidewall. The first notches may extend from the first trench to the internal area of the second plate. The second plate may define a second trench radially outward of the first trench, and a second sidewall may be defined between the second trench and the first trench.

A plurality of second notches may be defined in the second sidewall at the first surface of the second plate and radially distributed about the second sidewall. The second notches may extend from the second trench to the first trench. Each second notch of the plurality of second notches may be radially offset from a first notch of a plurality of first notches defined in the first sidewall. The plurality of first notches may include a greater number of notches than the plurality of second notches. A heater may be positioned between the first plate and the second plate. Each of the second apertures may be characterized by a radius greater than an outer annular radius of an annular member of the plurality of annular members.

Some embodiments of the present technology also encompasses semiconductor processing systems. The systems may include a remote plasma unit, and a processing chamber fluidly coupled with the remote plasma unit. The processing chamber may include a faceplate, a substrate support, and a showerhead. The showerhead may include a first plate characterized by a first surface in which a plurality of first apertures are defined. The first plate may further be characterized by a second surface opposite the first surface and from which second surface extend a plurality of annular members. Each annular member of the plurality of annular members may extend from a separate first aperture of the plurality of first apertures. A channel may be defined by each first aperture and corresponding annular member. The showerhead may also include a second plate coupled with the first plate. The second plate may be characterized by a first surface facing the first plate and a second surface opposite the first surface. A plurality of second apertures may be defined through the second plate within an internal area of the second plate. Each annular member of the plurality of annular members may extend within a separate second aperture of the plurality of second apertures.

In some embodiments, each of the second apertures may be characterized by a radius greater than an outer annular radius of an annular member of the plurality of annular members. The second plate may define a recessed ledge at an internal radius of the second plate, and the recessed ledge may define a boundary between the internal area and an external area of the second plate. The first surface of the second plate may be coated with a first material along the internal area of the first surface of the second plate, and the first surface of the second plate may be coated with a second material along at least a portion of the external area of the first surface of the second plate. The second material may be different from the first material. The second plate may define a first trench extending about the internal area radially outward of the recessed ledge. A first sidewall may be defined between the first trench and the internal area of the second plate. A plurality of first notches may be defined in the first sidewall at the first surface of the second plate and radially distributed about the first sidewall. The first notches may extend from the first trench to the internal area of the second plate. The second plate may define a second trench radially outward of the first trench. A second sidewall may be defined between the second trench and the first trench, and a plurality of second notches may be defined in the second sidewall at the first surface of the second plate and radially distributed about the second sidewall. The second notches may extend from the second trench to the first trench.

Some embodiments of the present technology may also encompass semiconductor processing chamber showerheads. The showerheads may include a first plate characterized by a first surface in which a plurality of first apertures are defined, and further characterized by a second surface opposite the first surface and from which second surface extend a plurality of first annular members. Each first annular member of the plurality of first annular members may extend from a separate first aperture of the plurality of first apertures. A first channel may be defined by each first aperture and corresponding first annular member. The showerheads may include a second plate characterized by a first surface facing the first plate in which a plurality of second apertures are defined, and further characterized by a second surface opposite the first surface and from which second surface extend a plurality of second annular members. Each second annular member of the plurality of second annular members may extend from a separate second aperture of the plurality of second apertures. A second channel may be defined by each second aperture and corresponding second annular member, and each first annular member of the plurality of first annular members may extend within a separate second channel. The showerheads may also include a third plate coupled with the second plate. The third plate may be characterized by a first surface facing the second plate and a second surface opposite the first surface. A plurality of third apertures may be defined through the third plate within an internal area of the third plate. Each second annular member of the plurality of second annular members may extend within a separate third aperture of the plurality of third apertures.

Such technology may provide numerous benefits over conventional systems and techniques. For example, surface coating may be facilitated by the present designs, which may reduce component wear. Additionally, multiple precursors may be delivered through the assembly while being maintained fluidly isolated from one another. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing tool according to some embodiments of the present technology.

FIGS. 2A-2B show schematic cross-sectional views of an exemplary processing chamber according to some embodiments of the present technology.

FIG. 3 shows a schematic plan view of an exemplary showerhead configuration according to some embodiments of the present technology.

FIG. 4 shows a schematic cross-sectional view of an exemplary processing chamber according to some embodiments of the present technology.

FIG. 5A shows a schematic cross-sectional view of an exemplary showerhead configuration according to some embodiments of the present technology.

FIG. 5B shows a schematic bottom plan view of an exemplary showerhead configuration according to some embodiments of the present technology.

FIG. 5C shows a schematic cross-sectional view of an exemplary showerhead configuration according to some embodiments of the present technology.

FIG. 6A shows a schematic plan view of an exemplary plate of an exemplary showerhead according to some embodiments of the present technology.

FIG. 6B shows a schematic view of a flow pattern through an exemplary plate of an exemplary showerhead according to some embodiments of the present technology.

FIG. 7 shows a schematic cross-sectional view of an exemplary showerhead configuration according to some embodiments of the present technology.

In the appended figures, similar components and/or features may have the same numerical reference label. Further, various components of the same type may be distinguished by following the reference label by a letter that distinguishes among the similar components and/or features. If only the first numerical reference label is used in the specification, the description is applicable to any one of the similar components and/or features having the same first numerical reference label irrespective of the letter suffix.

### DETAILED DESCRIPTION

The present technology includes improved gas distribution assembly or showerhead designs for distributing processing gases to produce flow patterns for forming deposition layers on a semiconductor substrate of a more uniform height and/or etching deposited layers in a more uniform fashion. While conventional showerhead designs may simply provide pass-through distribution systems for processing and precursor gases, the presently described technology allows for improved control of the flow characteristics of gases as they are delivered to a substrate processing chamber. In so doing, deposition operations may produce more accurate film profiles during manufacturing operations. Additionally, the present configurations may allow improved coating of component parts to limit interaction with plasma or other precursors, improving component lifetime over conventional designs.

Although some conventional gas distribution assemblies or showerheads may include multiple fluid channels covered by a plate, for example, such designs routinely suffer from gaps or deformations along the intersections of the plate with the portions of the body located between the channels and the inner walls. When the plate is coupled with the body, for example via bonding, brazing, etc., the plate may warp. Because the coupling may be performed around the outer edge and at multiple component connections, the amount of brazing or bonding may be extensive. Even slight warping of the plate may produce an uneven surface at the interfaces between the upper plate and body or lower plate, and interface locations where warping has occurred may not properly couple with the annular body.

As such, in operation, fluid may leak between fluid channels, as well as between fluid channels and a central region where precursors should be maintained separately. Such leakage can affect fluid delivery into the processing region, which can impact deposition or etching. Aspects of the present technology, however, overcome many if not all of these issues by providing components that are less likely to warp, and/or designs that are less impacted by warping, and may be free of brazing or component bonding, which may remove a risk of warping. By removing brazing, component removal and separation may also be afforded to allow improved and complete component cleaning and inspection that may not have been possible in conventional designs. Additionally, the present designs may include plate configurations that facilitate coating of the plates on surfaces to limit corrosion or erosion. After discussing systems incorporating the present designs, the disclosure will cover a number of showerheads and modifications according to aspects of the present technology. Although the discussion will routinely reference etching chambers, it is to be understood that the present technology may be incorporated into any semiconductor processing chamber or other system that may benefit from any of the number of advantages of the present technology.

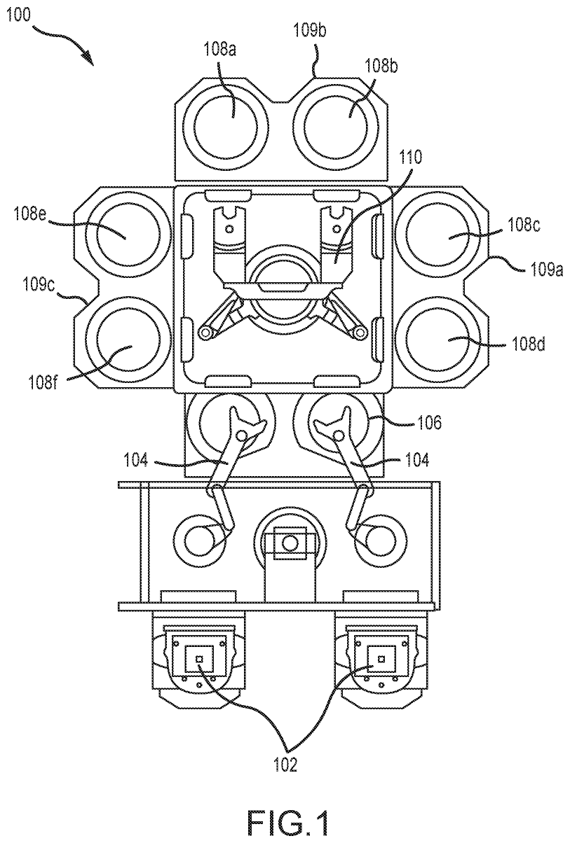

FIG. 1 shows a top plan view of one embodiment of a processing system 100 of deposition, etching, baking, and curing chambers according to disclosed embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching material films on the substrate wafer. In one configuration, two pairs of the processing chamber, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a material on the substrate. Any one or more of the processes described below may be carried out in chamber(s) separated from the fabrication system shown in different embodiments. It will be appreciated that additional configurations of deposition, etching, annealing, and curing chambers for dielectric films are contemplated by system 100. Many chambers may be utilized in the processing system 100, and may be included as tandem chambers, which may include two similar chambers sharing precursor, environmental, or control features.

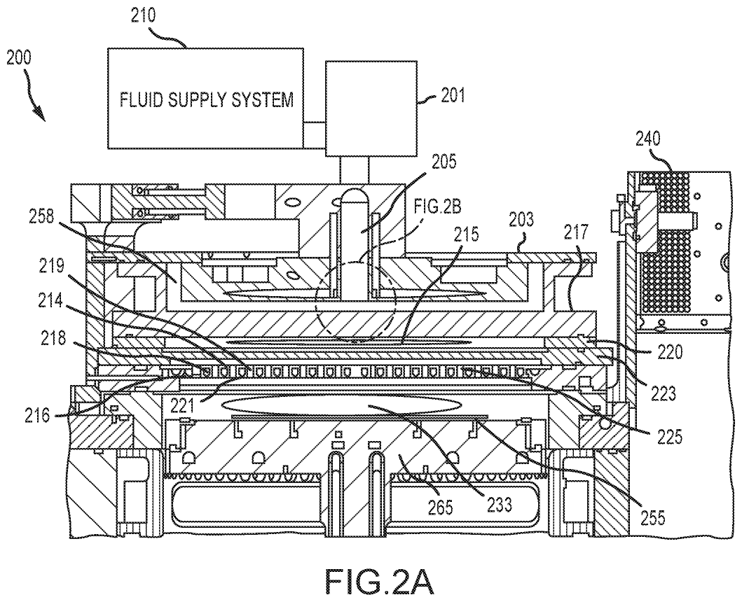

FIG. 2A shows a cross-sectional view of an exemplary process chamber system 200 with partitioned plasma generation regions within the processing chamber. During film etching, e.g., titanium nitride, tantalum nitride, tungsten, silicon, polysilicon, titanium oxide, silicon oxide, silicon nitride, silicon oxynitride, silicon oxycarbide, etc., a process gas may be flowed into the first plasma region 215 through a gas inlet assembly 205. A remote plasma system (RPS) 201 may optionally be included in the system, and may process a first gas which then travels through gas inlet assembly 205. The inlet assembly 205 may include two or more distinct gas supply channels where the second channel (not shown) may bypass the RPS 201, if included.

A cooling plate 203, faceplate 217, ion suppressor 223, showerhead 225, and a substrate support 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may comprise aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiNx:SiOx etch ratios, Si:SiOx etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

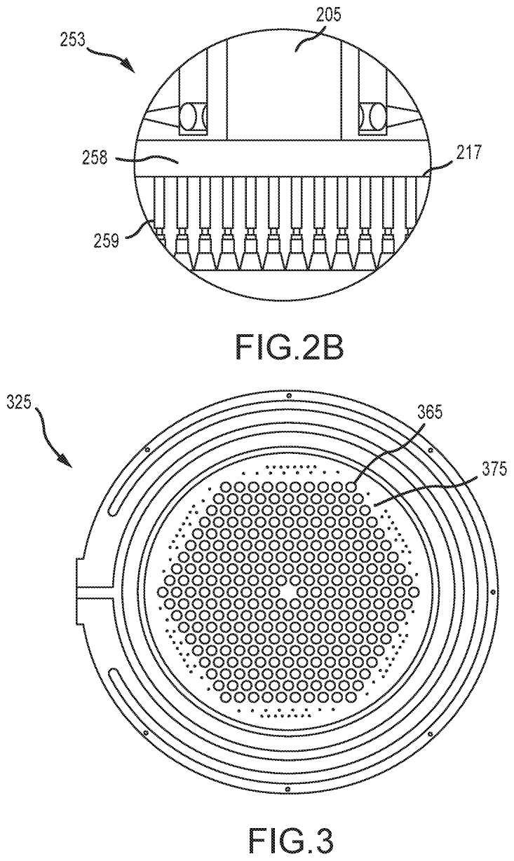

The gas distribution assemblies such as showerhead 225 for use in the processing chamber section 200 may be referred to as dual channel showerheads (DCSH) and are additionally detailed in the embodiments described in FIG. 3. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

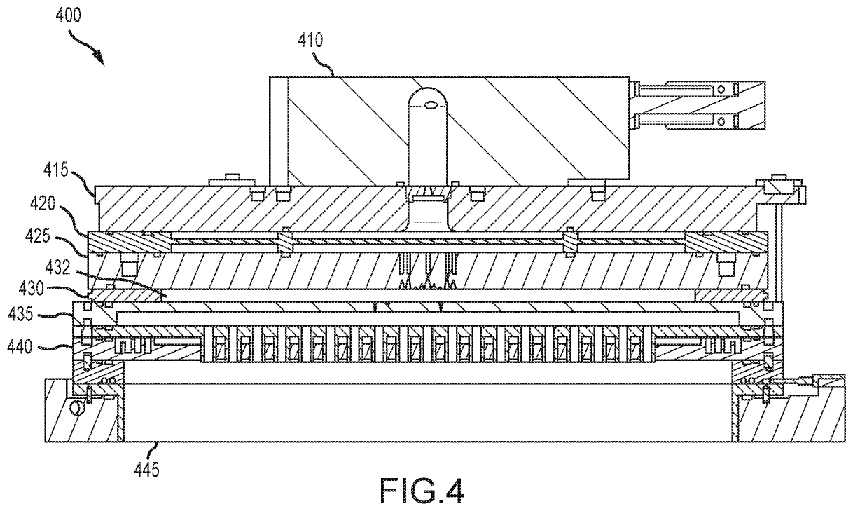

Turning to FIG. 4 is shown a schematic cross-sectional view of aspects of an exemplary processing chamber 400 according to some embodiments of the present technology. Processing chamber 400 may be similar to processing chamber 200 and may include some or all of the components or component characteristics described previously, and may show a partial view with a substrate pedestal within a processing region removed. For example, processing chamber 400 may include an RPS unit 410 coupled with the chamber and configured to deliver radical effluents of a precursor into the processing chamber. The chamber lid stack may include a number of components coupled together in any way, including in a removable manner, such as with removable couplings as opposed to brazing or bonding. For example, bolts, latches, screws, pins, or any other object which may compressibly couple the components together, but which may be removed to separate components may be used in some embodiments.

The components of the lid stack may include a number of features configured to deliver precursors in a more controlled or uniform manner, either for a uniform flow profile, or a uniform operation on a substrate. The stack may include a gasbox 415 coupled to receive effluents from the RPS unit, and may at least partially support the RPS unit. The gasbox 415 may distribute a radical and/or non-radical precursor laterally through the housing structure, and down through a blocker plate 420. Blocker plate 420 may provide further structure for distributing a precursor for uniformity. As shown, blocker plate 420 may define an interior zone and an exterior zone, which may be fluidly separate from one another. For example, the exterior zone may be at least partially annular and extend about the interior zone. Gasbox 415 may deliver equivalent amounts or different amounts of precursor to the separate zones defined by the blocker plate, depending on the intended effect on uniformity of delivery, distribution, or process effect.

Faceplate 425 may be coupled downstream of the blocker plate 420, and may contact the blocker plate, such as at radial edges, and/or along a partition of the blocker plate separating the interior and exterior zones. The contacting may maintain a separation of the precursor through the blocker plate zones, and may provide distribution paths to an interior zone defined radially by spacer 430. Spacer 430 may separate electrode components for plasma processing. For example, gasbox 415, blocker plate 420, and faceplate 425 may be electrically coupled in one or more ways, and may operate as a plasma generating electrode, which may afford plasma generation in interior region 432.

Downstream of the faceplate and/or spacer may be an ion suppressor 435, which may define the interior region 432 from below. Ion suppressor 435 may additionally operate as an electrode of the system by which plasma may be produced within interior region 432. Showerhead 440 may be coupled downstream of ion suppressor 435, and may provide multiple flow channels or pathways for delivering radical effluents into a processing region 445. Showerhead 440 may further define features for delivering an additional precursor or precursors into the processing region 445, which may be maintained fluidly isolated from precursors delivered through upstream components noted above. By maintaining precursors isolated through showerhead 440, interactions may be limited or prevented until entry in the processing region 445 in which a substrate may be housed as described above.

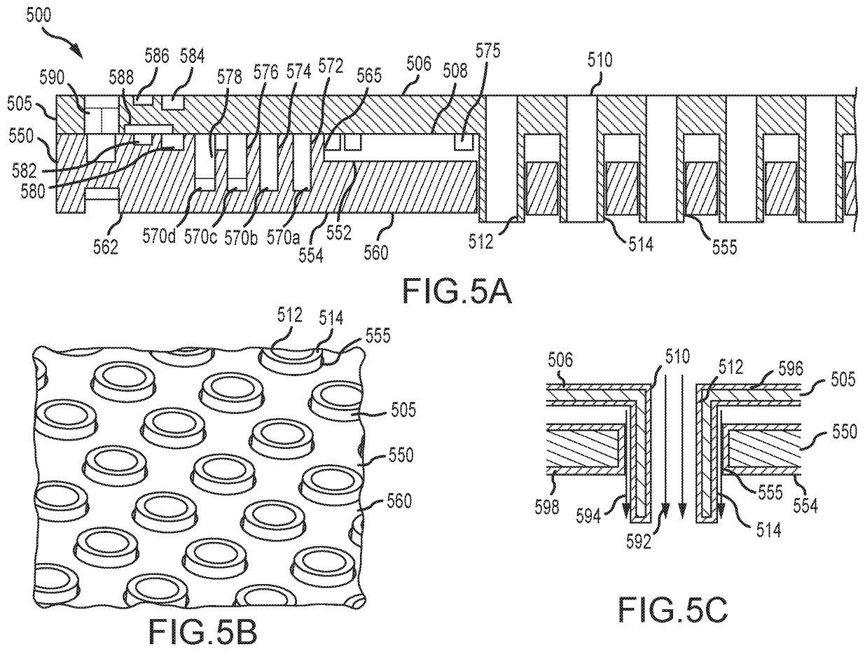

Showerhead 440 may be characterized by a number of features facilitating coating and component separation as described above. FIG. 5A shows a schematic cross-sectional view of an exemplary showerhead 500 according to some embodiments of the present technology. Showerhead 500 may include aspects of showerhead 440 or showerhead 225 described previously, and may be included in chamber 200 or 400 as well as any number of other processing chambers. Showerhead 500 may illustrate an exemplary showerhead configuration, which may be characterized by removable coupling. Conventional showerheads often include brazed or bonded components. Although cleaning fluids may be flowed within or through such showerheads, there may be no effective way of understanding the extent of cleaning due to the permanent coupling of the showerhead components. Accordingly, buildup and corrosion may occur within the showerhead, which may affect operation, such as fluid flow, as well as component lifetime.

Embodiments of the present technology may be coupled removably to allow complete cleaning and inspection of the constituent components, while maintaining a superior profile for flow distribution and precursor separation. Showerhead 500 illustrates a partial cross-section of the showerhead as illustrated in FIG. 4, and illustrates an exemplary two-plate showerhead design. The showerhead plates may or may not be brazed, bonded, or otherwise sealed together in some embodiments, and when not permanently coupled, may facilitate inspection and cleaning operations. The plates may also be formed to facilitate coating, such as by limiting features that may not be easily spray coated, for example.

The showerhead 500 may include a first plate 505, which may be an upper plate or an upstream plate in some embodiments. The first plate 505 may be characterized by a first surface 506 and a second surface 508, which may be opposite the first surface 506. The first surface 506 may define a plurality of apertures 510, which may be first apertures. The apertures may provide access to channels 512 defined by the first plate 505. A plurality of annular members 514 may extend from second surface 508, and may extend individually from separate apertures thereby defining the channels through showerhead 500. Accordingly, channels 512 may be defined by apertures 510 and corresponding annular members 514. In some embodiments, annular members 514 may be continuous extensions of first plate 505, where first plate 505 may be a single-piece design. Additionally, annular members 514 may be coupled with first plate 505 in any number of ways, such as brazing or bonding, or members 514 may be threaded, and apertures 510 may provide threaded recesses in which members 514 may be disposed.

Showerhead 500 may also include a second plate 550, which may be a lower plate or a downstream plate in some embodiments. The second plate 550 may be coupled with the first plate 505, such as along an outer radial area of the showerhead 500 as will be described further below. The second plate 550 may also be characterized by a first surface 552, and the first surface may face the first plate 505. Second plate 550 may also be characterized by a second surface 554, which may be opposite the first surface 552, and which may face or partially define a processing region. Second plate 550 may define a plurality of second apertures 555, which may extend through second plate 550 from the first surface 552 through second surface 554. Second plate 550 may be characterized by an internal area 560 and an external area 562 in some embodiments. Along the second surface 554, internal area 560 and external area 562 may transition seamlessly in some embodiments, however in some embodiments internal area 560 and external area 562 may be defined by one or more physical features of the plate, which may be defined, for example, along the first surface 552, as well as based on located features of the second plate 550.

For example, internal area 560 may be an area bounded by a hypothetical elliptical or polygonal figure extending about second apertures 555, for example, where all second apertures 555 are contained within an internal area of the second plate. In some embodiments, internal area 560 may extend further towards a feature of the second plate 550. As illustrated, first surface 552 of second plate 550 may define a recessed ledge 565 at an internal radius from a central axis through second plate 550. The ledge may be defined by first surface 552, and the ledge may define a boundary between the internal area 560 and the external area 562 of the second plate. The recessed ledge 565 may also define a thickness differential of the second plate 550 where the second plate is characterized by a first thickness across the internal area 560, and the second plate is characterized by a second thickness greater than the first across the external area 562.

In some embodiments the first plate 505 may be coupled with the second plate along or through the external area 562 of the second plate, and the first plate may at least partially contact the second plate along the external area 562. Based on the lesser thickness in the internal area 560, a separation may be formed between the first plate 505 and the second plate 550 in the internal area 560, and through this separation a volume may be formed between the second surface of the first plate and the first surface of the second plate amongst the annular members 514. A precursor may be flowed within this volume as will be described further below.

Each first aperture of the first apertures 510 defined in the first plate may be aligned with and concentric with an associated second aperture of the second apertures 555 defined in the second plate. When the first plate 505 and the second plate 550 are coupled, the annular members extending from the first apertures 510 may extend through the second apertures 555 as illustrated. Accordingly, each annular member 514 of the plurality of annular members may extend within a separate aperture 555 of the plurality of second apertures.

Second plate 550 may further define one or more trenches 570a-d. The trenches 570 may be defined within the external area 562 of the second plate, and may extend about the internal area 560 in some embodiments. Each trench 570 may be formed radially outward of the recessed ledge 565. For example, a first trench 570a may be formed radially outward of the recessed ledge 565, and a sidewall 572 may be defined between the first trench 570a and the internal area 560. A plurality of notches 575 may be formed in the first sidewall 572 at the first surface 552 of the second plate. Because the trench 570 may be formed in the external area of the second plate 550, the trench may be capped by the first plate 505. Notches 575 may provide fluid access from the first trench 570a into the internal area 560 and volume defined between the first plate and second plate of the showerhead. Notches 575 may be formed in a number of patterns along sidewall 572 as will be described further below, and may be radially distributed along the first sidewall. To afford fluid communication between the first trench 570a and the internal area 560, each notch 575 may extend from an external edge of the sidewall 572 defining an internal radius of the trench 570a to an internal edge of the sidewall 572 defining an external radius of the internal area 560, such as to the recessed ledge 565 as illustrated. Although in other embodiments apertures or other throughways may be defined within the sidewalls to provide fluid communication, notches may facilitate coating, and may afford complete coating of components of the present technology.

A second trench 570b may be defined by the second plate similar to the first trench 570a. The second trench may be formed radially outward of the first trench, and a second sidewall 574 may be defined between the first trench and the second trench. The second plate may further define a third trench 570c radially outward of the second trench 570b, and a third sidewall 576 may be defined between the second trench and the third trench. The second plate may further define a fourth trench 570d radially outward of the third trench 570c, and a fourth sidewall 578 may be defined between the third trench and the fourth trench. In embodiments any number of trenches may be formed to provide a flow pattern as will be described further below, and may include at least 1 trench, and may include greater than or about 2 trenches, greater than or about 3 trenches, greater than or about 4 trenches, greater than or about 5 trenches, greater than or about 6 trenches, greater than or about 7 trenches, or more trenches in some embodiments. The sidewalls may each define one or more notches, which will be discussed further below. Additionally, the trenches may extend a depth through the second plate 550, which may be greater than a depth of recessed ledge 565. Accordingly, trenches 570 may extend below a height of the internal area 560 of showerhead 500. Such a trench depth may facilitate uniformity of precursor flow as will be described further below.

Second plate 550 may define additional trenches radially outward of trenches 570. For example, an RF gasket may be seated within a trench and an elastomeric member, such as an o-ring, may be seated in a trench, with each seated in one of two trenches 580 and 582, which may be the radial outermost trenches in second plate 550. Similar trenches 584, 586 may be formed in first plate 505 for similar components. The RF gaskets may facilitate electrode operation of the showerhead in a plasma configuration as described previously. First plate 505 may in some embodiments define a heater trench 588 within second surface 508 of first plate 505. A heater may be positioned within the trench to provide a temperature control for the showerhead. Additionally, in some embodiments trench 588 may not be formed, and a heater may be positioned between the coupled first plate and second plate. For example, a thin film heater may be formed, positioned, or deposited along second surface 508 of the first plate 505 in a location proximate where trench 588 may otherwise be formed. Finally, coupling apertures may be defined in each plate for various couplings, such as bolt or fastener 590 coupling the first plate with the second plate proximate an exterior of the showerhead. As previously stated any number of couplings may be used to join the plates, although in some embodiments the couplings may be removable couplings and may not be permanent couplings, such as bonding, welding, brazing, or other materials limiting separation of the two plates from one another.

FIG. 5B shows a schematic bottom plan view of exemplary showerhead 500 according to some embodiments of the present technology. As illustrated, annular members 514 of first plate 505 may extend through second apertures 555 of second plate 550. The annular members 514 may be sized to maintain a gap between an outer annular edge of the annular members and a radial edge of plate 550 defining a diameter of second apertures 555. Additionally, annular members 514 may each extend a distance through a corresponding second aperture 555 beyond the second surface 560 of second plate 550. This may limit flow effects associated with fluids exiting channels 512. In some embodiments, the gap between the outer annular edge of the annular members and the radial edge of plate 550 defining the second apertures 555 may be defined by the annular members 514. For example, apertures and annular members may be uniformly sized across the component, or may vary between rows as will be discussed further below. Regardless, each second aperture may be characterized by a diameter or radius greater than an outer annular radius or diameter of an annular member of the plurality of annular members. Accordingly, a gap distance may be characterized as a width defined between an outer annular edge of the annular members, and an edge of or defining the second apertures. The gap distance may be any width depending on the size of the respective apertures, but may be characterized by a radial distance less than a length of extension past the second aperture by the annular members.

FIG. 5C shows a schematic cross-sectional view of an exemplary showerhead configuration according to some embodiments of the present technology, and may illustrate precursor flow within showerheads according to embodiments of the present technology. For example, the figure includes a first plate 505 including a number of annular members 514 extending from apertures 510 of the first plate. The schematic also includes a second plate 550 defining apertures 555 through which annular members 514 may extend. As shown, a gap may extend about the annular members 514, which may provide fluid communication from the volume defined between the plates, and entry for a second precursor into a processing region. A first precursor, which may include radical effluents from a remote plasma source within the chamber or from an RPS, may flow into the processing region through channels 512, as illustrated by flow lines 592. Additionally, a precursor flowed within the volume of the showerhead may exit by the annular gap formed between annular members 514 and second apertures 555, as illustrated by flow lines 594. The second precursor flowed into the volume may be prevented from flowing upstream by the plate coupling, and therefore may only exit from the showerhead through apertures 555.

Accordingly, the precursors may be maintained fluidly separate and isolated until they individually enter the processing region in which the substrate may be held, where they may interact or react according to the process being performed. This separation may provide numerous benefits including preventing a radical precursor from contacting a second precursor prior to reaching a reaction zone. By preventing the interaction of the gases, as one example, deposition within the chamber may be minimized prior to the processing region in which deposition is desired.

Although in embodiments annular members 514 may extend flush with second surface 554 of the second plate 550, as a precursor, such as radical effluents, exits the annular member, back diffusion may be afforded by the outward flow profile, which may be drawn up within the showerhead, and may allow interaction of the precursors within the volume between the plates.

This may allow deposition to occur, or etchants to be formed, which may damage or clog the showerhead. By extending the annular members an additional distance beyond the second surface of the second plate, a collimated effect may be introduced, which may limit or prevent back diffusion of the first precursor into the showerhead volume. Consequently, the annular members 514 may extend a distance beyond the second surface of the lower plate that is at least equal to the gap distance defined between the outer annular edge of the annular members, and the radial edge of the apertures 555. Additionally, the annular members 514 may extend past the second surface by greater than or about a multiplicative factor of this distance, and this factor may be greater than or about 2, 4, 6, 8, 10, 15, 20, 50, 100, or more depending on the properties of the effluents, or other desired flow effects for the first and/or second precursor.

FIG. 5C also illustrates coatings on the plates of the showerhead, which may be included in some embodiments. Conventional showerhead designs may include two sets of apertures in the second plate, where one set of apertures is axially aligned with apertures through the first plate, and which together form a flow channel for a first precursor. The second plate of some conventional designs may also include an additional set of apertures through which a second precursor may be flowed. One or more of these apertures may be smaller to facilitate more uniform delivery, although as these apertures continue to reduce in size, component coating may become more difficult. Additionally, by having axially aligned apertures used to develop the flow channel, often a number of brazing and bonding operations may be performed, which may prevent future separation of the two plates of the showerhead. Consequently, these conventional designs may be more likely to corrode due to the complex designs inhibiting component coating. Additionally, these conventional designs may be incapable of separation for component inspection and cleaning, which may require more frequent replacement due to insufficient cleaning.

By utilizing a first plate with extensions that incorporates the entire annular member design, showerheads according to embodiments of the present technology may be produced to sufficient aperture sizes where coating 596, such as spray coating or other coating processes, may fully coat all features of the component. Moreover, second plate 550 may be more fully coated as well. Because flow of a second precursor may be controlled by the gap distance formed between the apertures through the second plate and the outer circumference of the annular members, the second apertures themselves may be relatively larger than in conventional designs, while maintaining a flow path for the second precursor that is still relatively constricted to provide a more uniform delivery across the showerhead. Consequently, the gap width for the second precursor delivery may be maintained below or about 10 mm, and may be maintained below or about 9 mm, below or about 8 mm, below or about 7 mm, below or about 6 mm, below or about 5 mm, below or about 4 mm, below or about 3 mm, below or about 2 mm, below or about 1 mm, below or about 0.9 mm, below or about 0.8 mm, below or about 0.7 mm, below or about 0.6 mm, below or about 0.5 mm, below or about 0.4 mm, below or about 0.3 mm, below or about 0.2 mm, below or about 0.1 mm, or less. Additionally, because the second apertures themselves may be orders of magnitude larger in diameter from the gap, complete coating 598 may be provided about the second plate as well. Accordingly, because the components of showerheads according to the present technology may be more completely coated, they may be less likely to corrode or erode over time. Additionally, because coupling of the two plates may be limited to mechanical couplings in some embodiments, component separation may be easily performed to allow more thorough cleaning and inspection of the constituent parts, which may further improve overall showerhead lifetime.

The two plates of exemplary showerheads according to embodiments of the present technology may include any number of coatings, including multiple layers of coatings, partial coatings, different coatings including different coatings on different surfaces, or any number of various coatings, which may be determined based on precursors to which the components may be exposed, intended effect on precursors, intended operational characteristics including temperatures or other environmental conditions within a chamber, or any other criteria that may affect one or more coatings.

Components of the chamber, such as plates of the showerhead, may be exposed to both chemically reactive plasma effluents, such as fluorine, chlorine, or other halogen-containing effluents, as well as ions produced in a bias plasma used for physical modification at a processing level, as well as ions formed in a remote plasma, which may contact component surfaces. For example, first surface 506 of first plate 505, may be exposed to both plasma effluents of a plasma formed in a remote region of the chamber, which may be bounded by the plate, as well as reactive effluents proceeding through apertures 510 and channels 512 before exiting into a processing region. The second surface of the first plate, as well as the first surface of the second plate may be exposed to less reactive materials, or differently reactive materials, while these materials may or may not be plasma enhanced. Additionally, the first surface 552 of second plate 550 may also be exposed to plasma species such as bias plasma effluents formed in the processing region of the chamber and contacting the surface facing the substrate, as well as within apertures 555. Other components described above may also be exposed to one or both plasma effluents, including from backstreaming plasma effluents.

The plasma effluents may produce differing effects on the chamber components. For example, ions may be at least partially filtered by the showerhead from the chemically reactive plasma effluents produced in any remote plasma region. However, the reactive effluents, such as fluorine-containing effluents, for example, may cause corrosion of exposed materials, such as by forming aluminum fluoride. Over time, this process may corrode exposed metallic components, requiring replacement. Additionally, plasma species formed from a bias plasma in a processing region below second plate 550 of the showerhead may impact components causing physical damage and sputtering that may erode components over time. Accordingly, any of the described components may be susceptible to chemical corrosion as well as physical erosion from plasma effluents produced within one or more regions of the chamber.

Corrosion may be controlled in some ways by forming a coating over materials. For example, while aluminum may corrode from exposure to fluorine-containing plasma effluents, aluminum oxide, or other platings or coatings, may not corrode on contact with plasma effluents. Accordingly, any of the described components may be coated or protected by anodization, oxidation, electroless nickel plating, electroplated nickel, barium titanate, or any other material that may protect exposed conductive materials, such as aluminum, from chemical corrosion. Similarly, erosion may be controlled in some ways by forming a coating over materials. For example, high performance materials such as e-beam or plasma spray yttrium oxide, which may or may not include additional materials including aluminum or zirconium, for example, may protect the component from physical damage caused by bias plasma effluents. Damage to components may still occur, however, when a structure may be contacted by both corrosive plasma effluents as well as erosive plasma effluents.

Many corrosion resistant coatings may not extend beyond a micron or so in depth, if that much, and thus physical contact by bias plasma effluents may damage and strip the coating over time, which may reveal underlying conductive material, such as aluminum, which may then corrode from additional contact by plasma effluents from the etching process. For example, materials including electroless nickel plating, electroplated nickel, and barium titanate may be readily removed when contacted by erosive plasma effluents such as modifying plasma effluents. Additionally, the processes for forming erosion resistant coatings may be incapable of penetrating high aspect ratio features, and thus may not be capable of fully protecting components from erosion in conventional showerhead designs. The present technology, however, may utilize hybrid or combination coatings, which may provide sufficient protection to extend component life against both corrosion and erosion, and may fully coat exposed surfaces based on the showerhead plate designs previously described.

In an exemplary hybrid coating, a first layer may be or include an anodization, electroless nickel plating, electroplated nickel, aluminum oxide, or barium titanate in embodiments. A second layer of the hybrid coating may also be included externally to the first layer. The second layer may include yttrium oxide, or other high performance materials, such as e-beam coating or yttrium oxide including aluminum, zirconium, or other materials. The second layer may extend at least partially on all surfaces of the component, and may extend across a plasma-facing surface of the component, or any other surface. By forming the showerhead components to maintain larger aperture diameters, coating may easily penetrate the apertures.

Accordingly, complete coating of both layers can be formed and maintained on all surfaces of both plates individually, which may not be impacted during coupling operations, because the plates may not be coupled with brazing or other operations that may damage component coatings.

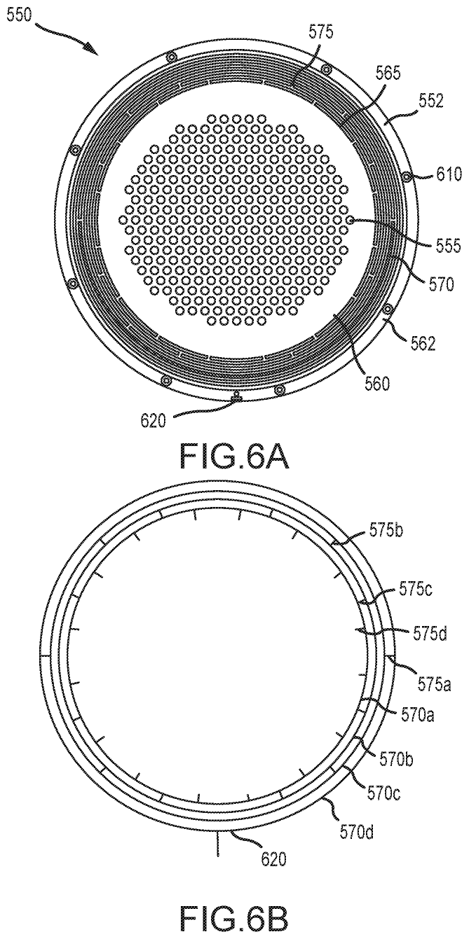

FIG. 6A shows a schematic plan view of an exemplary plate of an exemplary showerhead according to some embodiments of the present technology. For example, FIG. 6A may illustrate a top plan view of second plate 550. The second plate may include any of the characteristics previously described, and the figure may illustrate first surface 552 of second plate 550, which may show improved component features described previously, as well as additional features of the component. As shown, second plate 550 may include an internal area 560 separated from external area 562 by recessed ledge 565.

The second plate 550 may be a disk-shaped body, and may have a similar shape as the first plate, which may be understood as having similar dimensions to facilitate coupling. The second plate may have a diameter selected to mate with the diameter of the first plate, which may have apertures axially aligned with apertures 610 extending through second plate 550. Accordingly, coupling may occur by mechanical and removable coupling in the external area of the plate. The second apertures 555 may be arranged in a polygonal or elliptical pattern across the plate, such that an imaginary line drawn laterally across the centers of the outermost apertures define or substantially define a polygonal figure, which may be for example, a six-sided polygon as illustrated. Again, it is to be understood that a mating first plate as described above may have an identical aperture pattern so that annular members extending from the first plate may be concentric with and extend through the apertures of the second plate.

The pattern may also feature an array of staggered rows from about 5 to about 60 rows, such as from about 15 to about 25 rows of apertures. Each row may have, along the y-axis, from about 5 to about 20 first apertures 555, with each row being spaced between about 0.1 inches and about 1 inch apart. Each second aperture 555 in a row may be displaced along the x-axis from a prior aperture between about 0.1 and about 1 inches from each respective diameter. The second apertures 555, as well as the corresponding first apertures and annular members of the mating first plate, may be staggered along the x-axis from an aperture in another row by between about 0.1 and about 1 inches from each respective diameter. The second apertures 555 may be equally spaced from one another in each row.

The second apertures 555 may be arranged in a pattern that aligns with the pattern of the first apertures as described above. In one embodiment, when the first plate and second plate are positioned one on top of the other, the axes of the first apertures and second apertures may align. The plurality of first apertures and the plurality of second apertures may have their respective axes parallel or substantially parallel to each other, and for example, the apertures may be concentric as described above. Alternatively, the plurality of first apertures and the plurality of second apertures may have the respective axes disposed at an angle from about 1° to about 30° from one another. At the center of the second plate 550 there may be no second aperture 555.

In one example, each concentric ring of apertures 555 may have an additional number of apertures based on the geometric shape of each ring. In the example of a six-sided polygon, each ring moving outwardly may have six apertures more than the ring located directly inward, with the first internal ring having six apertures. With a first ring of apertures located nearest to the center of the first and second plates, the first and second plates may have more than two rings, and depending on the geometric pattern of apertures used, may have between about one and about fifty rings of apertures. Alternatively, the plates may have between about two and about forty rings, or up to about thirty rings, about twenty rings, about fifteen rings, about twelve rings, about ten rings, about nine rings, about eight rings, about seven rings, about six rings, etc. or less. In one example, as shown in FIG. 6A, there may be nine hexagonal rings on the exemplary upper plate.

The concentric rings of apertures may also not have one of the concentric rings of apertures, or may have one of the rings of apertures extending outward removed from between other rings. The rings may still also have certain apertures removed from the geometric pattern. For example again with reference to FIG. 6A, a tenth hexagonal ring of apertures may be formed on the plate shown as the outermost ring. However, the ring may not include apertures that would form the vertices of the hexagonal pattern, or other apertures within the ring.

FIG. 6A also shows an additional view of the trenches 570 formed about the external area of the showerhead, and as previously described. The trenches may be formed concentrically and may be positioned radially outward of one another with a sidewall in between. Each sidewall may define one or more notches 575 providing fluid access between trenches. By utilizing notches formed at the top of the trenches, more conformal and complete coating may be facilitated as previously explained. The trenches may be formed in similar patterns on each sidewall between the trenches, or may be formed differently at each sidewall to affect flow properties between the trenches. For example, the notches may be formed to produce a recursive flow pattern, which may increase uniformity of delivery into the internal area and internal volume of the showerhead.

In some embodiments second plate 550 may include multiple coatings. As previously described, the first plate and the second plate may include different coatings on different surfaces, and any number of coating variations may be performed to protect the parts. Additionally, in some embodiments the second plate 550 may include a different coating along the internal area than in the external area, such as along the first surface of the second plate. For example, the trenches 570 may provide extended delivery of a precursor delivered into a port of the second plate, and may in one sense be considered an extended fluid delivery line. Accordingly, in some embodiments, the external area of the second plate, and more specifically within and across the trenches, may be coated with a material to mimic or be similar to an actual delivery line that may couple with a port 620 of the showerhead plate. For example, in some embodiments the external area of the second plate may be coated with nickel to be similar to a nickel-coated delivery line, while the internal area on the first surface may be coated with one or more coatings described above, including a hybrid coating. Any number of other variations of multiple coatings on a surface of a plate of the showerhead are similarly encompassed.

FIG. 6B shows a schematic view of a flow pattern through an exemplary plate of an exemplary showerhead according to some embodiments of the present technology. For example, FIG. 6B may illustrate a schematic view of the trenches and notches formed in plate 550 of FIG. 6A. Some embodiments of showerheads according to the present technology may include a single port 620 into a side portion of the second plate of the showerhead, which may provide a second precursor to the chamber. In other embodiments multiple fluid lines may be used. If flowed directly into the internal area of the showerhead, the delivery through the apertures into a processing region would not likely be uniform, and may impact the processes performed. By forcing the precursor to traverse a series of trenches, delivery into the central region may be more uniformly performed, which may increase uniformity from the showerhead.

As shown, port 620 may deliver a second precursor into a first trench 570, which may correspond to trench 570d discussed above, and which may distribute the precursor in both directions about the first trench. The precursor may reach two notches 575a formed between the fourth trench 570d and a third trench 570c formed radially inward of the first trench. The notches 575a may be formed on substantially opposite sides of the first trench from one another, or in any other location, and the precursor, after flowing through the notches may then extend in four directions about the third trench 570c. Next, the precursor may reach four notches 575b radially distributed about the third trench 570c and providing access to a second trench 570b radially inward of the second trench. The notches 575b may be formed in any location about the trench, but in some embodiments as illustrated, the notches are formed equidistantly from the first notches, and radially offset a partial turn to position a second notch 575b at a similar distance from a previous first notch 575a in both directions within the next trench, and which may provide a similar distance to each second notch. This may increase uniformity of flow. Similarly, eight notches may be formed about second trench 570b providing fluid access to a first trench 570a. Again, the notches 575c may be radially offset from the previous notches 575b to again provide an equal flow path in each direction from the previous notches.

Finally, first trench 570a may include sixteen notches 575d through a final sidewall, such as the recessed ledge defining the internal area, and may provide a number of paths distributed about the inner circumference of the fourth trench. This may substantially equally distribute the precursor about the showerhead to have more uniform delivery into the internal area. It should be understood that FIG. 6A illustrates but one example of any number of flow trench and notch configurations similarly encompassed by the present technology. Embodiments may include more or less trenches, more or less notches, or other variations to impact flow distribution. In some embodiments, an innermost set of notches may include a greater number of notches than an outer set of notches, and in some embodiments, each inward trench may define a greater number of notches from an inner sidewall than may be formed through an outer sidewall of the trench.

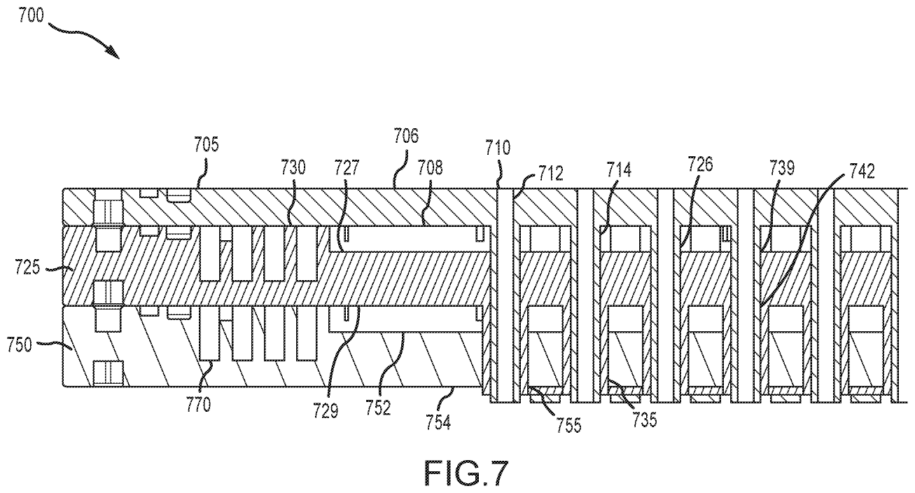

Turning to FIG. 7 is shown a schematic cross-sectional view of an exemplary showerhead 700 configuration according to some embodiments of the present technology. FIG. 7 may illustrate a showerhead having many similar components of any of the previous designs, while incorporating a third plate to facilitate a third precursor into a processing chamber. The explanation of FIG. 7 may similarly be extended to cover any number of additional plates as would be understood by a skilled artisan. Showerhead designs according to the present technology may produce a nested incorporation of plates, where the annular members of a first plate extend within apertures of a second plate. This concept may be extended by incorporating any number of hybrid plates incorporating aspects of both the first plate and the second plate as described above. It is to be understood that any of the plates of FIG. 7 may include any of the aspects, characteristics, and coatings previously described, and the showerhead of FIG. 7 may be used in any chamber, which may be used to incorporate multiple precursors that may be maintained fluidly isolated prior to accessing a processing region of the chamber.

FIG. 7 may include a first plate 705, which may be similar to first plate 505 described above, and may include some or all of the features previously discussed. For example, first plate 705 may define first apertures 710 defined in a first surface 706, and first annular members 714 extending from a second surface 708 opposite first surface 706. The apertures 710 and first annular members 714 may define first channels 712 through showerhead 700. Showerhead 700 may also include a second plate 750, which may define a plurality of second apertures 755 extending from first surface 752 through second surface 754, and through which first annular members 714 may extend, as previously described. Second plate 750 may also define one or more trenches 770, which may be similar to trenches 570, and which may provide a flow path for an additional precursor to be delivered into a volume of the showerhead, and may provide the additional precursor through the second apertures 755 into a processing region, or lower region of a chamber, where the precursor may interact with additional precursors.

Showerhead 700 may also include a third plate 725, which may have some features of both the first plate 705 and the second plate 750. For example, third plate 725 may include a number of trenches 730 through which a third precursor may be delivered into the showerhead. The third trenches 730 may be similar to trenches 770 or 570 as previously described, and may include a recursive flow pattern as discussed above. The third plate 725 may define the trenches 730 in a first surface 727, which may face the first plate 705. Third plate 725 may also define a plurality of third apertures 726 within the first surface 727, and which may receive the first annular extensions 714 extending from first plate 705. Third plate 725 may also include a plurality of second annular members 735 extending from a second surface 729 of the third plate. The second surface 729 may face the second plate 750. Apertures 755 of the second plate may also receive the second annular extensions through the second plate, and may receive the first apertures within the second apertures as illustrated. An additional volume may be defined between the third showerhead and the first showerhead in an internal area of the third showerhead, which may allow a third precursor to be delivered to the showerhead by the third plate, and which may operate similar to the second plate, and include similar characteristics as described above.

Apertures 710, 726, and 755 may each be characterized by an increasing diameter to accommodate a separate gap between the annular extensions being received and the radial edge of the apertures, and which may provide a delivery path for the precursors. Accordingly, apertures 726 may maintain an annular gap 739, which may allow delivery of the third precursor through a second annular channel defined between the outer annular radius of the first annular members 714, and the inner annular radius of the second annular members 735. In this way, apertures 710 may be characterized by a radius less than the radius of apertures 726, and apertures 726 may be characterized by a radius less than the radius of apertures 755. The annular wall thickness may also be adjusted to maintain particular gap distances in some embodiments. Additionally, to limit back streaming of any precursor as previously described, second annular members 735 may extend beyond second surface 754 of second plate 750 a distance as described above. Additionally, first annular members 714 may extend a greater distance beyond second surface 754 of second plate 750, as well as a distance beyond second annular members 735. This may further prevent mixing of precursors prior to delivery into the processing region, although in some embodiments, second annular members 735 may extend beyond first annular members 714, which may allow a certain amount of mixing of two of the three precursors prior to delivery into the processing region. Although not described here, the plates of the showerheads may also have any of the features of the previously described showerheads, and may operate as previously described.

In operation, the showerhead 700 may be configured such that two fluids may be delivered into the showerhead from the side, but maintained fluidly separate in two fluidly isolated volumes produced in the assembly. A first fluid may be delivered from above the showerhead 700 and may include radical species produced in an RPS or first plasma region, for example. The first fluid may flow through the first plurality of fluid channels 712 that may be individually isolated and may not be accessed from within the assembly volumes. A second fluid may be introduced into the showerhead from a side port or first delivery channel that delivers the second fluid between the first plate 705 and the intermediate or third plate 725. The second fluid may flow within this first defined volume and through the second plurality of fluid channels 742, which may be shaped as the annular gap 739 due to insertion of the annular members 714. These channels and volume may also be fluidly isolated from the other channels formed through the assembly. A third fluid may be introduced into the showerhead from an additional side port or second delivery channel that delivers the third fluid between the intermediate plate 725 and the lower or second plate 750. The third fluid may flow within this second defined volume and through the third plurality of fluid channels, which may all be fluidly isolated from the other channels formed through the assembly.

The additional side port or second delivery channel, as well as the second defined volume, may be fluidly isolated from the first delivery channel and first defined volume. In this way, three fluids may be delivered to a processing region through a single gas distribution assembly, but may be separated until they each exit the gas distribution assembly and enter the processing region. Additionally, because the upper plates may each form channels within the extensions, precursors may not escape the volumes to flow upstream, and may only have fluid paths downstream from the showerhead. By using showerheads according to embodiments of the present technology, a number of advantages may be afforded over conventional multiple channel showerheads. The present configurations may afford more complete and uniform coatings based on the aperture sizing and designs, which may maintain relatively small delivery channels for added precursors. Additionally, the components may be coupled with removable couplings, and which may include no bonding or brazing, thereby providing enhanced access to each individual component for additional cleaning, inspection, or replacement.

In the preceding description, for the purposes of explanation, numerous details have been set forth in order to provide an understanding of various embodiments of the present invention. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the disclosed embodiments. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the smallest fraction of the unit of the lower limit, unless the context clearly dictates otherwise, between the upper and lower limits of that range is also specifically disclosed. Each smaller range between any stated value or intervening value in a stated range and any other stated or intervening value in that stated range is encompassed. The upper and lower limits of those smaller ranges may independently be included or excluded in the range, and each range where either, neither, or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an aperture” includes a plurality of such apertures, and reference to “the plate” includes reference to one or more plates and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or steps, but they do not preclude the presence or addition of one or more other features, integers, components, steps, acts, or groups.

What is claimed is:

1. A semiconductor processing chamber showerhead comprising:
a first plate characterized by a first surface in which a plurality of first apertures are defined, further characterized by a second surface opposite the first surface and from which second surface extend a plurality of annular members, each annular member of the plurality of annular members extending from a separate first aperture of the plurality of first apertures, wherein a channel is defined by each first aperture and corresponding annular member; and
a second plate coupled with the first plate, wherein the second plate is characterized by a first surface facing the first plate and a second surface opposite the first surface, wherein a plurality of second apertures are defined through the second plate within an internal area of the second plate, and wherein each annular member of the plurality of annular members extends within a separate second aperture of the plurality of second apertures.

2. The semiconductor processing chamber showerhead of claim 1, wherein each annular member of the plurality of annular members extends a distance through a corresponding second aperture beyond the second surface of the second plate.

3. The semiconductor processing chamber showerhead of claim 1, wherein the second plate defines a recessed ledge at an internal radius of the second plate, and wherein the recessed ledge defines a boundary between the internal area and an external area of the second plate.

4. The semiconductor processing chamber showerhead of claim 3, wherein the first surface of the second plate is coated with a first material along the internal area of the first surface of the second plate.

5. The semiconductor processing chamber showerhead of claim 4, wherein the first surface of the second plate is coated with a second material along at least a portion of the external area of the first surface of the second plate, and wherein the second material is different from the first material.

6. The semiconductor processing chamber showerhead of claim 3, wherein the second plate defines a first trench extending about the internal area radially outward of the recessed ledge, and wherein a first sidewall is defined between the first trench and the internal area of the second plate.

7. The semiconductor processing chamber showerhead of claim 6, wherein a plurality of first notches are defined in the first sidewall at the first surface of the second plate and radially distributed about the first sidewall, wherein the first notches extend from the first trench to the internal area of the second plate.

8. The semiconductor processing chamber showerhead of claim 6, wherein the second plate defines a second trench radially outward of the first trench, and wherein a second sidewall is defined between the second trench and the first trench.

9. The semiconductor processing chamber showerhead of claim 8, wherein a plurality of second notches are defined in the second sidewall at the first surface of the second plate and radially distributed about the second sidewall, and wherein the second notches extend from the second trench to the first trench.

10. The semiconductor processing chamber showerhead of claim 9, wherein each second notch of the plurality of second notches is radially offset from a first notch of a plurality of first notches defined in the first sidewall.

11. The semiconductor processing chamber showerhead of claim 10, wherein the plurality of first notches comprises a greater number of notches than the plurality of second notches.

12. The semiconductor processing chamber showerhead of claim 1, wherein a heater is positioned between the first plate and the second plate.

13. The semiconductor processing chamber showerhead of claim 1, wherein each of the second apertures is characterized by a radius greater than an outer annular radius of an annular member of the plurality of annular members.

14. A semiconductor processing system comprising:
a remote plasma unit; and
a processing chamber, fluidly coupled with the remote plasma unit, the processing chamber comprising:
a faceplate;
a substrate support;
a showerhead comprising:
a first plate characterized by a first surface in which a plurality of first apertures are defined, further characterized by a second surface opposite the first surface and from which second surface extend a plurality of annular members, each annular member of the plurality of annular members extending from a separate first aperture of the plurality of first apertures, wherein a channel is defined by each first aperture and corresponding annular member; and
a second plate coupled with the first plate, wherein the second plate is characterized by a first surface facing the first plate and a second surface opposite the first surface, wherein a plurality of second apertures are defined through the second plate within an internal area of the second plate, and wherein each annular member of the plurality of annular members extends within a separate second aperture of the plurality of second apertures.

15. The semiconductor processing system of claim 14, wherein each of the second apertures is characterized by a radius greater than an outer annular radius of an annular member of the plurality of annular members, wherein the second plate defines a recessed ledge at an internal radius of the second plate, and wherein the recessed ledge defines a boundary between the internal area and an external area of the second plate.

16. The semiconductor processing system of claim 15, wherein the first surface of the second plate is coated with a first material along the internal area of the first surface of the second plate, and wherein the first surface of the second plate is coated with a second material along at least a portion of the external area of the first surface of the second plate, and wherein the second material is different from the first material.

17. The semiconductor processing system of claim 16, wherein the second plate defines a first trench extending about the internal area radially outward of the recessed ledge, and wherein a first sidewall is defined between the first trench and the internal area of the second plate.

18. The semiconductor processing system of claim 17, wherein a plurality of first notches are defined in the first sidewall at the first surface of the second plate and radially distributed about the first sidewall, wherein the first notches extend from the first trench to the internal area of the second plate.

19. The semiconductor processing system of claim 17, wherein the second plate defines a second trench radially outward of the first trench, wherein a second sidewall is defined between the second trench and the first trench, wherein a plurality of second notches are defined in the second sidewall at the first surface of the second plate and radially distributed about the second sidewall, and wherein the second notches extend from the second trench to the first trench.

20. A semiconductor processing chamber showerhead comprising:
a first plate characterized by a first surface in which a plurality of first apertures are defined, further characterized by a second surface opposite the first surface and from which second surface extend a plurality of first annular members, each first annular member of the plurality of first annular members extending from a separate first aperture of the plurality of first apertures, wherein a first channel is defined by each first aperture and corresponding first annular member;
a second plate characterized by a first surface facing the first plate in which a plurality of second apertures are defined, further characterized by a second surface opposite the first surface and from which second surface extend a plurality of second annular members, each second annular member of the plurality of second annular members extending from a separate second aperture of the plurality of second apertures, wherein a second channel is defined by each second aperture and corresponding second annular member, and wherein each first annular member of the plurality of first annular members extends within a separate second channel; and
a third plate coupled with the second plate, wherein the third plate is characterized by a first surface facing the second plate and a second surface opposite the first surface, wherein a plurality of third apertures are defined through the third plate within an internal area of the third plate, and wherein each second annular member of the plurality of second annular members extends within a separate third aperture of the plurality of third apertures.
